(19) United States
(12) Patent Application Publication
(10) Pub. No.: US 2010/0090214 A1
(43) Pub. Date: Apr. 15, 2010

(54) OXIDE THIN FILM AND OXIDE THIN FILM DEVICE

(75) Inventors: Ken Nakahara, Kyoto (JP); Hiroyuki Yuji, Kyoto (JP); Kentaro Tamura, Kyoto (JP); Shunsuke Akasaka, Kyoto (JP); Masashi Kawasaki, Miyagi (JP); Akira Ohtomo, Miyagi (JP); Atsushi Tsukazaki, Miyagi (JP)

Correspondence Address: RABIN & Berdo, PC, 1101 14TH STREET, NW, SUITE 500, WASHINGTON, DC, 20005, US

(73) Assignee: ROHM CO., LTD., Kyoto-fu (JP)

(21) Appl. No.: 12/450,614

(22) PCT Filed: Apr. 2, 2008
(86) PCT No.: PCT/JP2008/056563

§ 371 Date: Oct. 2, 2009

(30) Foreign Application Priority Data
Apr. 4, 2007 (JP) 2007-098815

(51) Int. Cl. H01L 29/22

(52) U.S. Cl. 257/43; 257/E29.094

(57) ABSTRACT

Provided are an oxide thin film doped with an n-type impurity, and an oxide thin film device. In an oxide thin film (2), as shown in FIG. 1(b), doped oxide layers (2a) doped with an n-type (electron-conductivity type) impurity and undoped oxide layers (2b) not doped with an n-type impurity are laminated in an alternating and repeated manner. When an oxide layer is doped with the n-type impurity at a high concentration, roughness of a surface of the oxide layer becomes large. For this reason, the doped oxide layers (2a) are covered with the undoped oxide layers (2b) capable of ensuring surface flatness, before surface roughness attributable to the doped oxide layers (2a) becomes very large. Thus, a flat oxide thin film can be formed.

### TECHNICAL FIELD

The present invention relates to an oxide thin film doped with an n-type impurity, and an oxide thin film device.

### BACKGROUND ART

There are, for example, nitrides and oxides as compounds containing an element of a gaseous simple substance. With respect to the nitrides, the industrial success of blue LEDs has generated a large market and various research themes. On the other hand, the oxides, such as superconductive oxides represented by YBCO, transparent conductive materials represented by ITO, and giant magnetic resistance materials represented by (LaSr)MnO₃, have been one of the hottest research fields for having properties so various to the extent impossible by conventional semiconductors, metals and organic materials.

Incidentally, it is a common practice that a device which develops a unique function is produced by laminating and etching several thin films having different functions; however, thin film forming methods for oxides are limited to sputtering, PLD (pulsed laser deposition) and the like. For this reason, it is difficult to fabricate lamination structures as with semiconductor devices. The sputtering has difficulty in obtaining a crystal thin film, and the PLD has difficulty in obtaining a uniform thin film in a large area due to its employing point evaporation basically, although being capable of forming a crystal thin film, therefore being unsuitable for mass production except for studies.

As a method by which structures as with a semiconductor device can be produced, there has been proposed a plasma assisted molecular beam epitaxy (PAMBE). PAMBE is a method improved upon MBE, having been used in mass production of GaAs-based devices, for fabrication of crystal thin films of compound semiconductors, such as oxides and nitrides, each including any gaseous element in composition, for example, GaN and ZnO. The MBE method is a method used in mass production of GaAs-based devices, and has a good track record for crystal growth apparatuses for semiconductor devices.

PAMBE is a method enabled to enhance reactivity of a gaseous element such as oxygen or nitrogen by disassembling molecular structures by use of plasma, and thereby to produce a crystal thin film of an oxide or a nitride on the basis of the MBE method. Thereby, high-quality GaN and ZnO thin films have become producible by MBE.

Incidentally, a semiconductor is generally subjected to doping in which a controlled amount of impurity is deliberately added to a substance serving as a mother body. Since doping derives various functions from the semiconductor so as to achieve large-scale functions by controlling conductivity types of p-type and n-type as desired, doping-control technologies are important.

Take ZnO, which is one of the oxides, as an example. It has been difficult to grow ZnO as a semiconductor device material, although multifunctionality, the size of light emission potential and the like of ZnO have attracted attention. This results from the largest drawback thereof, i.e. acceptor doping is difficult to perform and thereby a p-type ZnO has been unobtainable. In recent years, however, researches thereof have become popular under a situation where the technological advancements have made it possible to obtain a p-type ZnO and further to achieve light emission of the p-type ZnO, as seen in Non-patent Documents 1 and 2.

Non-patent Document 1: A. Tsukazaki et al., Japanese Journal of Applied Physics vol. 44 (2005) L643

Non-patent Document 2: A. Tsukazaki et al., Nature Material vol. 4 (2005) 42

Non-patent Document 3: C. Harada et al., Materials Science in Semiconductor Processing vol. 6 (2003) 539

Non-patent Document 4: K. Nakahara et al., Applied Physics Letters vol. 79 (2001) 4139

### DISCLOSURE OF THE INVENTION

### Problems to be Solved by the Invention

On the other hand, Ga or the like has been used as a dopant of an electron-conductive type, that is, an n-type. As for the oxides, control of doping has been difficult. This is because, if doping concentrations are made high to some degree as with a Ga-doped ZnO shown in Non-patent Documents 3 and 4, complex oxides are often inevitably produced due to the reasons such as: it is easy to produce composite oxides with doping materials except for those of gaseous elements, as is apparent in view of unlimited possibility of oxides each having a large number of elements; and reaction activities are enhanced by plasma in PAMBE.

Furthermore, it is often the case that a semiconductor device is provided with unique functions by accumulation of thin films having been subjected to different doping, thin films having different compositions, and the like. On such an occasion, flatness of the thin films is often a problem. If flatness of the thin films is poor, indeed various problems arise such as: the thin films act as resistance when a carrier moves in the thin film; surface roughness becomes worse on the upper part of a lamination structure; uniformity of etching depths cannot be secured due to the surface roughness; and anisotropic growth of a crystal plane occurs due to the surface roughness. All of those problems are equally obstacles in exerting desired functions of the semiconductor device. For this reason, surfaces of the thin films usually need to be made as flat as possible all over necessary areas.

However, for example, a Ga-doped ZnO has not only a problem that control of doping is difficult as described above, but also a problem that flatness of a ZnO-based thin film doped with an impurity Ga cannot be maintained. FIG. 8 shows, as one example, an AFM image of a MgZnO film uniformly doped with Ga. FIG. 8(a) and FIG. 8(b) are surface images of Ga-doped MgZnO films grown respectively at a Ga cell temperature of 600° C. and a Ga cell temperature of 550° C. The resistance in FIG. 8(a) is 2 kΩ, while the resistances in FIG. 8(b) is 5 kΩ. Thus, surface roughness shown in FIG. 8(a) is larger where irregularities are noticeable on a surface of the Ga-doped MgZnO film, no flat film is formed, and the Ga cell temperature is higher (an amount of Ga doping is larger).

The present invention has been made to solve the above problems, and an object thereof is to provide an oxide thin film capable of forming a flat film with an n-type impurity doped therein, and an oxide thin film device.

### Means for Solving the Problems

In order to achieve the above-mentioned object, an invention according to claim 1 is an oxide thin film formed on a substrate, characterized in that: the oxide thin film is doped with an n-type impurity; and concentrations of the n-type impurity are modulated.

Additionally, an invention according to claim 2 is the oxide thin film according to claim 1, characterized in that the modulation of concentrations of the n-type impurity is formed by repetition of high and low levels of concentrations of the n-type impurity.

Additionally, an invention according to claim 3 is the oxide thin film according to claim 2, characterized in that the repetition of higher and lower levels of concentrations of the n-type impurity is repetition of doping and undoping.

Additionally, an invention according to claim 4 is the oxide thin film according to any one of claims 1 to 3, characterized in that the modulation of concentrations of the n-type impurity is carried out within oxide thin films of the same combination composition ratio.

Additionally, an invention according to claim 5 is the oxide thin film according to any one of claims 1 to 4, characterized in that a more highly concentrated part in the modulation of concentrations of the n-type impurity is not more than 1×10²¹ cm⁻³.

Additionally, an invention according to claim 6 is the oxide thin film according to any one of claims 1 to 5, characterized in that a specific resistance of the oxide thin film is not more than 1 Ωcm.

Additionally, an invention according to claim 7 is the oxide thin film according to any one of claims 1 to 6, characterized in that the oxide thin film is a ZnO-based oxide.

Additionally, an invention according to claim 8 is the oxide thin film according to any one of claims 1 to 7, characterized in that the n-type impurity is a IIIB group element.

Additionally, an invention according to claim 9 is the oxide thin film according to any one of claims 1 to 8, characterized in that a surface flatness of the oxide thin film is not more than a root-mean-square roughness of 10 nm.

Additionally, an invention according to claim 10 is an oxide thin film device formed of an oxide thin film laminate including the oxide thin film according to any one of claims 1 to 9.

Additionally, an invention according to claim 11 is the oxide thin film device according to claim 10, characterized by including an undoped oxide thin film on the oxide thin film laminate.

Additionally, an invention according to claim 12 is the oxide thin film device according to claim 11, characterized in that the undoped layer is a light emitting layer.

### EFFECTS OF THE INVENTION

In the oxide thin film according to the present invention, an n-type impurity is not doped uniformly in a lamination direction but doped with higher and lower levels of concentration obtained by modulating the concentration of the n-type impurity in the lamination direction. Thus, a region having a lower level of concentration covers and flattens roughness in a region having a higher level of concentration. This makes it possible to form an oxide thin film having a favorable flatness as a whole. In particular, when n-type impurity doped layers and undoped layers are alternated, the undoped layers bury irregularities of the doped layers. Thus, an oxide thin film having a favorable flatness can be obtained. A flatness of an undoped film is formable by a method disclosed in Japanese Patent Application Nos. 2007-27182 and 2007-27702 by the present inventors.

### BRIEF DESCRIPTION OF THE DRAWINGS

FIG. 1 is a view showing a structure of an oxide thin film in which n-type impurity concentrations of the present invention are formed through modulated doping.

FIG. 2 is a chart showing relationships of Ga cell temperatures with Ga concentrations and specific resistances.

FIG. 3 is a table showing key numeric values in each of sample points in FIG. 2.

FIG. 4 is a chart showing an analysis result obtained by an XRD.

FIG. 5 is a view showing a surface image of a MgZnO thin film in which n-type impurity concentrations are formed through modulated doping.

FIG. 6 is a view showing a surface image of a MgZnO thin film in which n-type impurity concentrations are formed through modulated doping.

FIG. 7 is a view showing a surface image of an undoped ZnO thin film.

FIG. 8 is a view showing a surface image of a ZnO thin film in which an n-type impurity is doped uniformly in a lamination direction.

FIG. 9 is a view showing one example of an oxide thin film device using the oxide thin film of the present invention.

FIG. 10 is a view showing one example of an oxide thin film device using the oxide thin film of the present invention.

### EXPLANATION OF REFERENCE NUMERALS

1 growth substrate
2 oxide thin film
2a doped oxide thin film layer
2b undoped oxide thin film layer

### BEST MODE FOR CARRYING OUT THE INVENTION

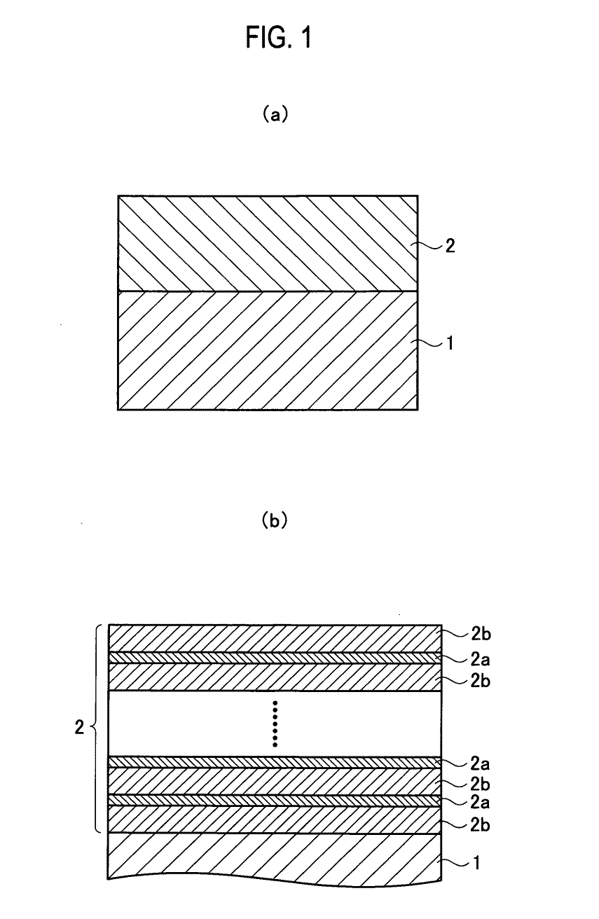

One embodiment of the present invention will be described below with reference to the accompanying drawings. FIG. 1 shows a structure of an oxide thin film according to the present invention. As shown in FIG. 1(a), an oxide thin film 2 is prepared on a growth substrate 1 by a PAMBE method or the like. At that time, in the oxide thin film 2, as shown in FIG. 1(b), undoped oxide layers 2b not having an n-type impurity (of an electron-conductive type) doped therein, and doped oxide layers 2a having the n-type impurity doped therein are laminated in an alternating and repeated manner. Note that the oxide thin film 2 may have, in each of compounds having the same element composition ratio, plural regions formed in a lamination direction among which concentrations only of the n-type impurity are respectively modulated, or may be configured so that concentrations of the n-type impurity may be different by compounds having different element composition ratios. Additionally, lamination sequences may be switched so that the undoped oxide layer 2b may be laminated after the doped oxide film 2a.

Additionally, modulation of concentrations of the n-type impurity may be formed not through combination of doped layers and undoped layers but through combination of doped layers, which may be, for example, combination of regions doped with the n-type impurity at high concentrations, and regions doped with the n-type impurity at low concentrations. Also, the combination may be formed by alternately repeating highly concentrated doped layers and lowly concentrated doped layers, or may be formed so that concentrations may be lowered stepwise sequentially from more highly concentrated doped layers to more lowly concentrated doped layers.

If the oxide thin film is formed in the above described manner, irregularities (roughness) generated in the n-type impurity doped regions or highly concentrated regions are flattened by being buried by the undoped regions or lowly concentrated regions. Particularly in order to bury irregularities of the film, use of the undoped regions such as the undoped oxide layers 2b, is the most desirable.

Next, for the purpose of observing the above-mentioned content, a description will be first given of what happens when Ga (gallium) serving as the n-type impurity is doped at high concentration to a ZnO thin film, which is taken as an example of a ZnO-based thin film used for the oxide thin film.

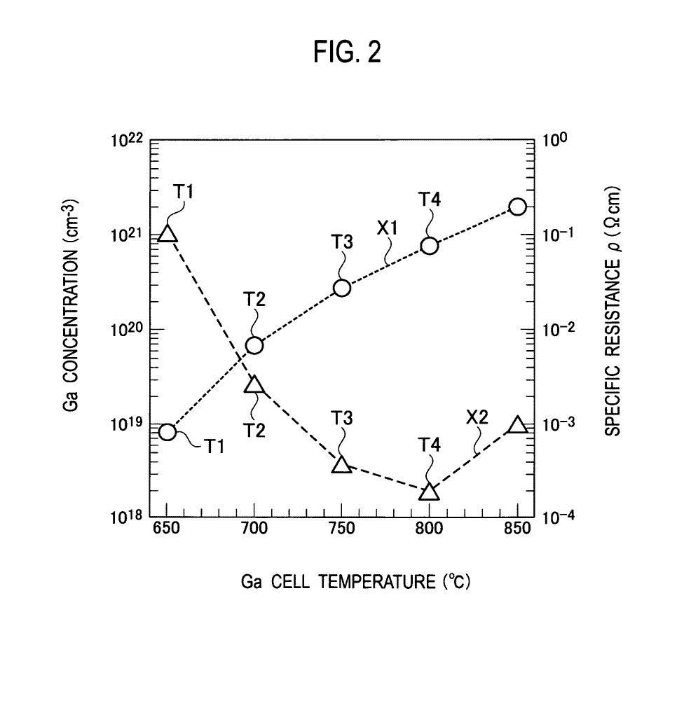

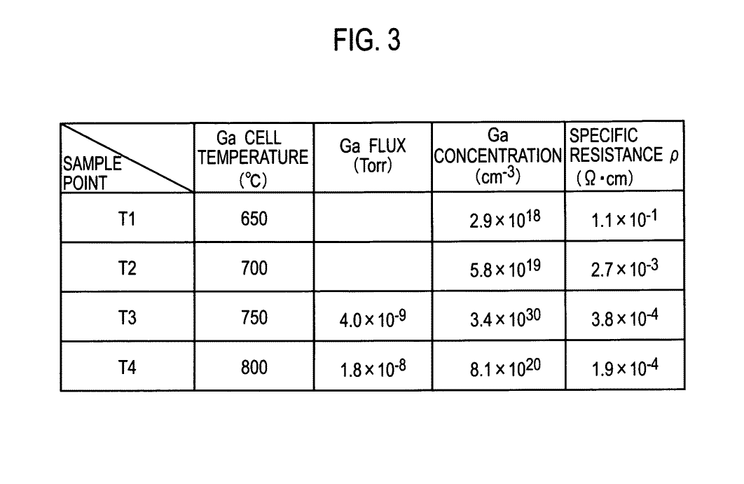

FIG. 2 shows one obtained by growing a Ga doped ZnO thin film on an A-face sapphire substrate (corresponding to the growth substrate 1), and FIG. 3 shows a Ga cell temperature, a ZnO flux, a concentration of the n-type impurity Ga, and a specific resistance pin each of sample points in FIG. 2. Note that more detailed growth conditions are described in “K. Nakahara et al., Japanese Journal of Applied Physics vol. 43 (2004) L180”.

The left vertical axis in FIG. 2 indicates a Ga concentration (cm⁻³) in the Ga doped ZnO thin film, and a graph X1 plotted with open circles corresponds to this scale. On the other hand, the right vertical axis in FIG. 2 indicates specific resistance ρ (Ωcm), and a graph X2 plotted with open triangles corresponds to this scale. Additionally, the horizontal axis indicates Ga cell temperature. Key numeric values in each of the sample points T1 to T4 described in FIG. 2 are shown in FIG. 3.

As shown in FIGS. 2 and 3, as the Ga cell temperature is raised, an amount of Ga introduced into the ZnO thin film increases. Then, if the Ga concentration in the ZnO thin film increases, the specific resistance goes decreasing. However, although the specific resistance goes sequentially decreasing until the Ga cell temperature increases to 800° C., the specific resistance increases contrariwise, while the Ga concentration still increases, when the Ga cell temperature increases to 850° C. This indicates that, while Ga works as an element that supplies electrons to the insides of ZnO crystals, Ga works as a donor impurity in a normal manner because increases in the Ga amount are accompanied by increases in carrier concentration and decreases in specific resistance.

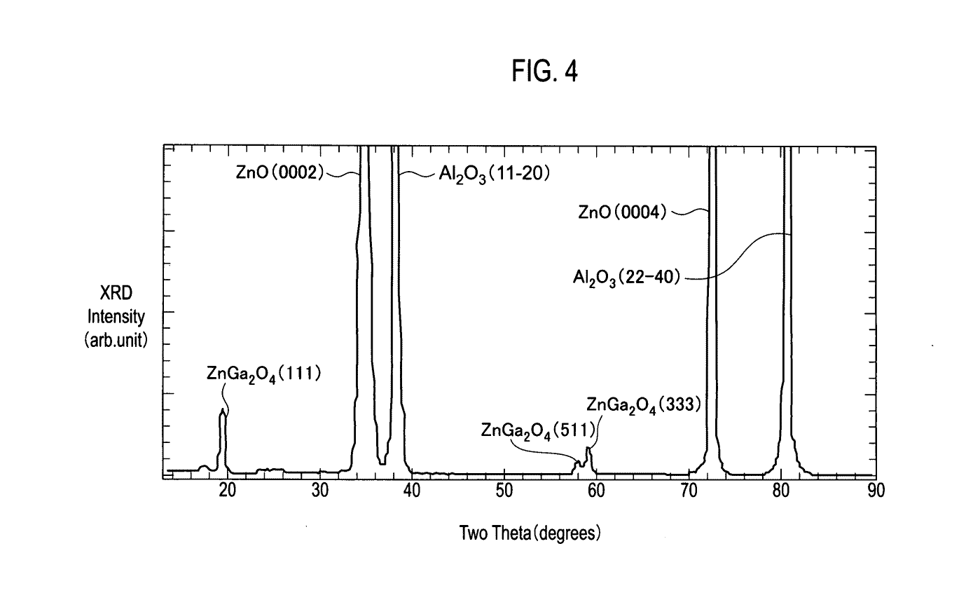

However, an abnormal change occurs after the Ga cell temperature exceeds 800° C., and the supplied Ga amount exceeds 1×10²¹ cm⁻³. As has been described above, it becomes impossible to lower the specific resistance although the donor is being added. With respect to the ZnO thin film in a state where the specific resistance increased contrariwise even with Ga concentration having increased, crystals were analyzed by use of an X-ray diffractometer (XRD). A result of the analysis is shown in FIG. 4, by which it was found that XRD peaks other than those of ZnO were observed. From peak analysis, it was found that this film contains a complex oxide that is ZnGa₂O₄.

Oxygen forms compounds with any other elements, and kinds of the compounds are indeed various, and large in number. Consequently, it indicates that, even when the n-type impurity Ga is underway, after the supplied Ga amount exceeds a certain value (1×10²¹ cm⁻³), Ga comes to be contained in the order of several percents in ZnO crystals. Thus, dopant Ga and ZnO serving as a mother body are automatically converted into mixed crystals.

A description will be given below of how the above-described general properties exert influence on flatness of a thin film necessary for a semiconductor device. Experiments were conducted with ZnO-based oxides formed as oxide thin films. Each of the ZnO-based oxides is one composed of ZnO or a compound including ZnO, and is meant as one whose specific examples include, in addition to ZnO, oxides of: a IIA-group element and Zn; a IIB-group element and Zn; and a IIA-group element, a IIB-group element and Zn.

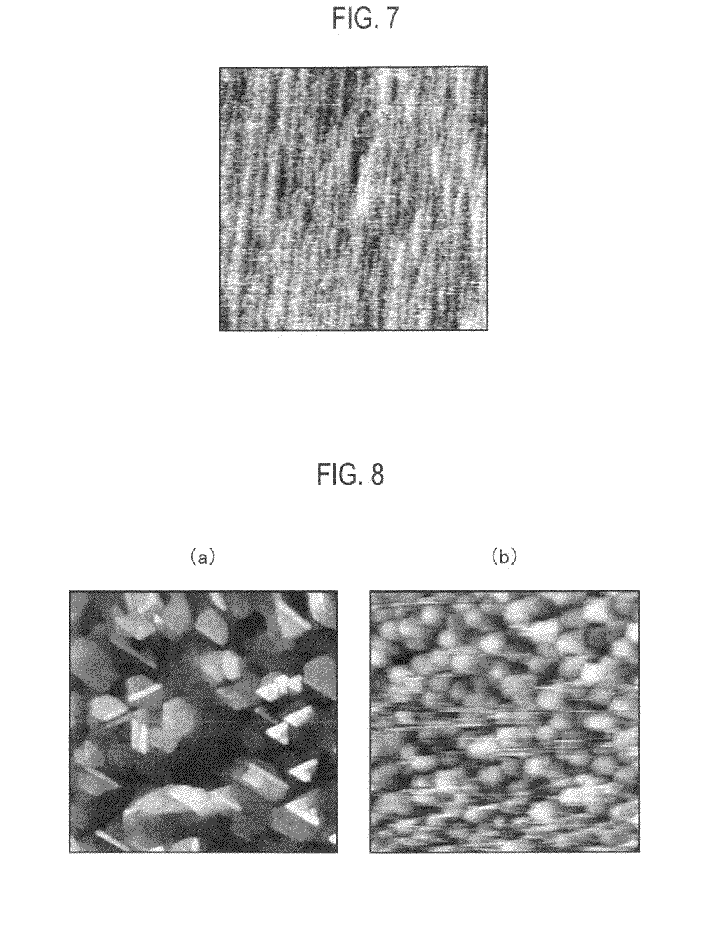

In FIGS. 7 and 8, AFM images of various Ga-doped MgZnO films (the ZnO-based oxides), and growth conditions of these were as follows. Substrate temperatures were set to 770° C. to 800° C.; Mg cell temperatures, 350° C.; Zn cell temperatures, 275° C. to 280° C.; Ga cell temperatures, 450° C. to 600° C.; growth time lengths, one hour; and Mg compositions, 10%.

FIG. 7 shows a surface image of an undoped MgZnO film, and FIG. 8 shows, as has been described above, a surface image of a MgZnO film in which Ga was doped uniformly in a lamination direction, where: FIG. 8(a) shows the film grown with a Ga cell temperature of 600° C.; and FIG. 8(b) shows the film grown with a Ga cell temperature of 550° C. As shown in FIG. 8, the MgZnO films in which Ga was doped uniformly in a lamination direction had rough surfaces. However, roughness can scarcely be observed on a surface of the undoped MgZnO film of FIG. 7. The surface thereof looks good. Here, a root mean square (RMS) is 0.2 nm.

As will be known if Ga flux data in FIG. 1 is looked at, Ga fluxes in these cases were not more than a background pressure, 1×10⁻⁹ Torr, of MBE, and doping amounts can be estimated to have been about 1×10¹⁹ cm⁻³ at most. The reason why surface conditions were severely influenced with those low levels is thought to be as follows.

In a case of a thin film that is MgZnO, temperatures of Ga, Zn and Mg at which vapor pressures thereof become 1×10⁻⁶ Torr are 742° C., 177° C. and 246° C., respectively, and Ga is greatly lower in vapor pressure. Being lower in vapor pressure means being less likely to re-evaporate even if a substrate temperature has risen, that is, being able to stay on a substrate surface for long time and thereby having a higher probability of being introduced into the film. This is because ΔP=(supplied vapor power−parallel vapor pressure), which is a source of a driving force for gas phase growth, is large.

It is considered that, as a result, mixed crystallization occurred with a small vapor pressure because an introduced proportion became higher than the case of Zn and Mg and a percentage of the number of introduced atoms to the number of supplied atoms was greatly higher than the case of Zn and Mg. Since this principle itself is not limited to MgZnO as a matter of course, a similar phenomenon occurs when an oxide having a very large difference in ΔP is grown.

On the other hand, as to an n-type dopant, an element belonging to the IIIB group such as B (boron), Al (aluminum), In (indium) or Tl (thallium) is extremely lower in vapor pressure than other elements forming an oxide other than gaseous elements, and therefore, as has been described above, comes to have a higher rate of being introduced into the film and have a higher probability of being crystallized, whereby formation of a flat film becomes more difficult. Consequently, when not only Ga but also an element belonging to the IIIB group is used as a dopant of an oxide thin film, a flat film can be obtained by employment of a lamination structure of highly concentrated doped layers and lowly concentrated doped layers as with one configuration of the present invention.

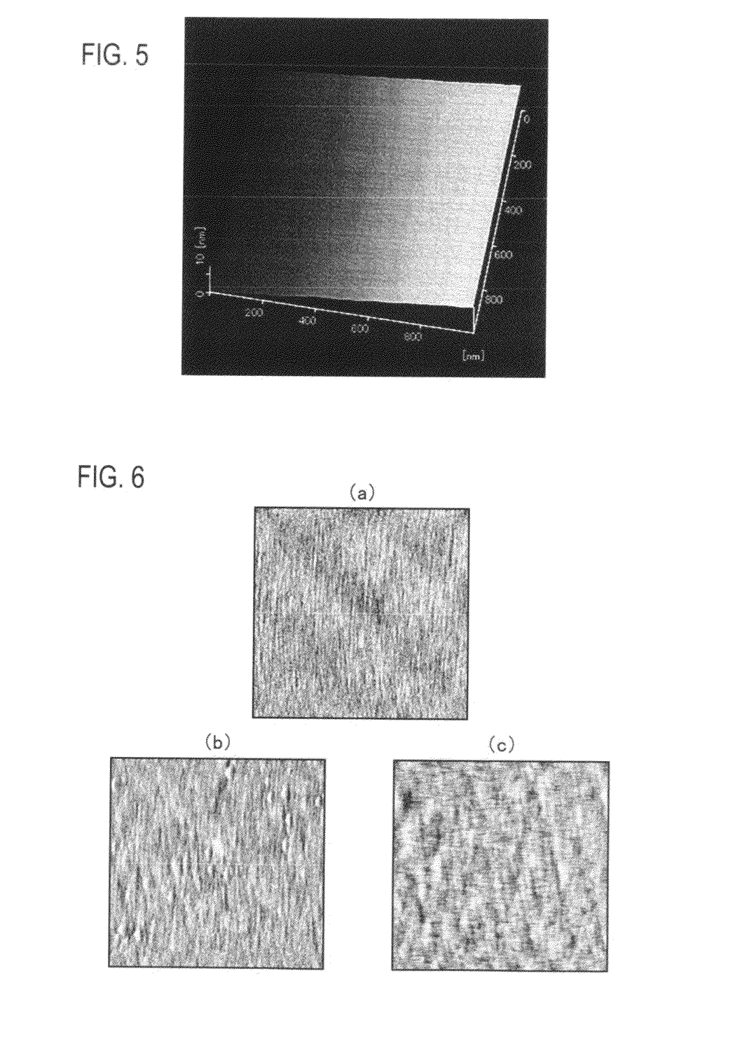

In FIGS. 5 and 6, Ga-doped MgZnO obtained by a technique shown FIG. 1(b), which is one of the configurations of the present invention, is shown. Films were formed by a method in which, before surface roughness attributable to a Ga doped MgZnO layer (the doped oxide layer 2a) becomes very large, the Ga doped MgZnO layer is covered with an undoped MgZnO layer (the undoped oxide layer 2b) with which surface flatness can be ensured.

With the Ga doped MgZnO layer of 1 nm and the undoped MgZnO layer of 3 nm being taken as one cycle, each of the films in FIGS. 5 and 6 was formed with 500 cycles. This modulation of Ga doping concentration was formed by repeatedly opening and closing a shutter of a Ga cell. Fabrication was carried out with a Ga cell temperature of 550° C. Additionally, FIG. 6(a) is a surface image with an AFM resolution of 20 μm; FIG. 6(b), with an AFM resolution of 5 μm; FIG. 6(c), with an AFM resolution of 2 μm; and FIG. 5, with an AFM resolution of 1 μm. At that time, a sheet resistance of the film was 1 kΩ, and was sufficient for the film to be, for example, used as a clad layer provided in relation to a light-emitting layer (an active layer). As can be found from FIGS. 5 and 6, in the structure of the present invention, almost no irregularities were observed on a surface of the last layer having been subjected to the modulated doping. RMS was 1 to 0.2 nm when being measured in any scales.

The present invention is not limited to the above example. Although combination of highly concentrated Ga-doped MgZnO layers and lowly concentrated Ga doped MgZnO layers may be employed, a difference in vapor pressure is large in the case of ZnO. Thus, combination of the Ga-doped MgZnO layers and undoped MgZnO layers is desirable. It is desirable that a thickness of each of the Ga doped MgZnO layers be not exceeding approximately about 10 nm. The thickness of each undoped layer does not matter since the undoped layer is provided for the purpose of ensuring the flatness. Here, a resistance value increases as the undoped layer is made thicker. Thus, the thickness thereof may be determined in accordance with specifications required for a device to be fabricated.

A formation method of such a ZnO-based thin film as mentioned above will be described. The growth substrate 1 is set in a load lock chamber, and is heated for 30 minutes at the temperature of 200° C. in a vacuum environment of about 1×10⁻⁵ to 1×10⁻⁶ Torr for moisture removal. Through a transportation chamber having vacuum of about 1×10⁻⁹ Torr, the substrate is introduced into a growth chamber having wall faces having been cooled with liquid nitrogen, and the ZnO-based thin film is grown by use of an MBE method.

By use of a Knudsen cell in which high-purity Zn of 7N has been put in a crucible made of PNB, Zn is supplied in the form of a Zn molecular beam by being heated to about 260° C. to 280° C. and sublimated. Mg is one example of the IIA group elements. Mg is also supplied in the form of a Mg molecular beam by use of high-purity Mg of 6N by being heated to about 300° C. to 400° C. and sublimated from a cell of the same structure.

By use of O₂ gas of 6N, oxygen is supplied as an oxygen source after being brought into an oxygen radical state where reactive activity is heightened by, with plasma being generated by application of RF high frequency waves of about 100 W to 500 W, being supplied at about 1 sccm to 5 sccm to an RF radical cell through a stainless steel tube having an electrolytically polished inner face, the RF radical cell being provided with a discharge tube having a cylinder through which a small orifice is made. Plasma is essential, and an ZnO-based film cannot be formed with introduction of raw gas of O.

Additionally, by use of a Knudsen cell in which high-purity Ga has been set in a crucible made of PNB, Ga is supplied in the form of a Ga molecular beam by being heated and sublimated. For the substrate, a carbon heater coated with SiC is used in the case of general resistance heating. A metal-based heater made of W or the like cannot be used since the heater becomes oxidized. While there are other heating methods such as lump heating and laser heating, any method may be employed as long as the method is resistant to oxidization.

After being heated to 750° C. and being heated for about 30 minutes in a vacuum of about 1×10⁻⁹ Torr, ZnO thin film growth is started by opening of shutters of an oxygen radical cell and an Zn cell. On the other hand, in the case of an MgZnO thin film, thin film growth is started by opening of a shutter of a Mg cell as well. When Ga doping is carried out, a shutter of a Ga cell is opened, and a doping amount is controlled through Ga cell temperatures. When an undoped thin film is formed, the shutter of the Ga cell is closed.

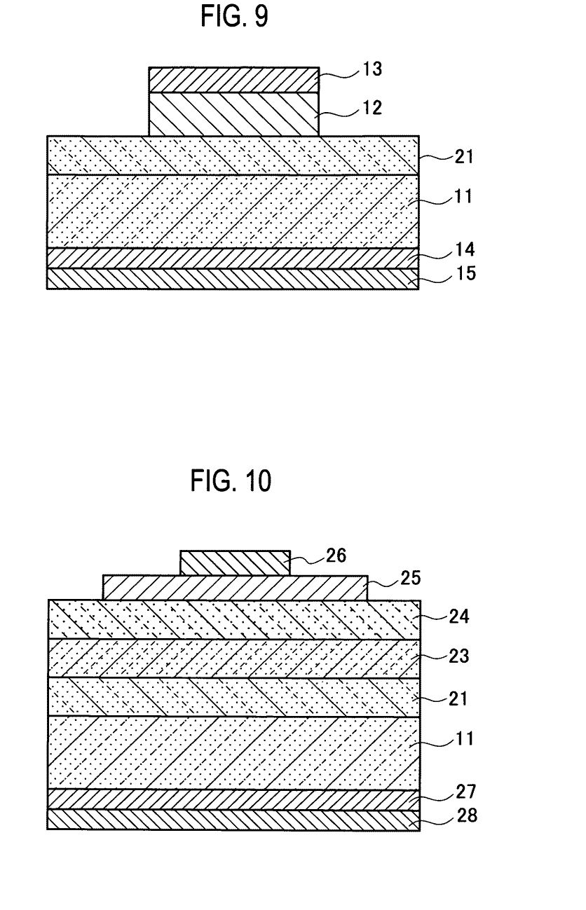

Next, an oxide thin film device using the above described oxide thin film will be described with an example of a ZnO-based thin film. FIG. 9 shows a configuration of a Schottky diode as one example of the oxide thin film device. An n-type MgZnO layer 21 is formed on a ZnO substrate 11, a PEDOT:PSS layer 12 is laminated thereon, and an Au film 13 used for wire bonding and the like is formed on the PEDOT:PSS layer 12. On the other hand, on a back surface of the ZnO substrate 11, an electrode composed of multilayer metal films of a Ti film 14 and an Au film 15 are formed.

Here, the n-type MgZnO layer 21 is configured as a layer having been subjected to modulated doping with an n-type impurity according to the present invention, and is composed, for example, in the same manner as the structure of the oxide thin film 2 of FIG. 1(b). Note that PEDOT: PSS is one obtained by doping a polythiophene derivative (PEDOT: poly (3,4)-ethylenedioxithiophene) with polystyrene sulfonate (PSS). This device presents a commutating action like a Schottky diode when the Au film 13 and Au film 15 of the device in FIG. 9 are connected to positive and negative sides of an electronic circuit, respectively.

FIG. 10 shows a configuration of an LED (light emitting diode) as one example of the oxide thin film device. The n-type MgZnO layer 21, an undoped ZnO-based MQW layer 23 and a p-type MgZnO layer 24 are sequentially formed on the ZnO substrate 11, and an electrode composed of multilayer metal films of a Ni film 25 and an Au film 26 is formed on the p-type MgZnO layer 24. On the other hand, on the back surface of the ZnO substrate 11, an electrode composed of multilayer metal films of a Ti film 27 and an Au film 28 are formed.

Here, the n-type MgZnO layer 21 is configured as a layer having been subjected to modulated doping with an n-type impurity according to the present invention, and is composed, for example, in the same manner as the structure of the oxide thin film 2 of FIG. 1(b). Additionally, the undoped ZnO-based MQW layer 23 is a light-emitting layer (an active layer) having a multiple quantum well structure in which several cycles of undoped MgZnO and undoped ZnO are alternately laminated, and the device in FIG. 10 has a double heterostructure having the light-emitting layer sandwiched between the p-type MgZnO layer 24 and the n-type MgZnO layer 21.

1. An oxide thin film formed on a substrate, characterized in that
the oxide thin film is doped with an n-type impurity; and
concentrations of the n-type impurity are modulated.

2. The oxide thin film according to claim 1, characterized in that the modulation of the concentrations of the n-type impurity is formed by repetition of high and low levels of concentrations of the n-type impurity.

3. The oxide thin film according to claim 2, characterized in that the repetition of high and low levels of the concentrations of the n-type impurity is repetition of doping and undoping.

4. The oxide thin film according to claim 1, characterized in that the modulation of the concentrations of the n-type impurity is carried out within oxide thin films of the same combination composition ratio.

5. The oxide thin film according to claim 1, characterized in that a highly concentrated part in the modulation of concentrations of the n-type impurity is not more than 1×10²¹ cm⁻³.

6. The oxide thin film according to claim 1, characterized in that a specific resistance of the oxide thin film is not more than 1 Ωcm.

7. The oxide thin film according to claim 1, characterized in that the oxide thin film is a ZnO-based oxide.

8. The oxide thin film according to claim 1, characterized in that the n-type impurity is a IIIB group element.

9. The oxide thin film according to claim 1, characterized in that a surface flatness of the oxide thin film is a root-mean-square roughness of not more than 10 nm.

10. An oxide thin film device formed of an oxide thin film laminate including the oxide thin film according to claim 1.

11. The oxide thin film device according to claim 10, characterized by comprising an undoped oxide thin film on the oxide thin film laminate.

12. The oxide thin film device according to claim 11, characterized in that the undoped layer is a light emitting layer.
